(19) United States
(12) Patent Application Publication
(10) Pub. No.: US 2025/0309116 A1
(43) Pub. Date: Oct. 2, 2025

(54) BACKSIDE GATE TIE-DOWN IN BACKSIDE POWER DISTRIBUTION NETWORK (BSPDN) ARCHITECTURE

(71) Applicant: International Business Machines Corporation, Armonk, NY (US)

(72) Inventors: Chen Zhang, Santa Clara, CA (US); Ruilong Xie, Niskayuna, NY (US); Debarghya Sarkar, Latham, NY (US); Tao Li, Slingerlands, NY (US)

(21) Appl. No.: 18/621,051

(22) Filed: Mar. 28, 2024

(51) Int. Cl. H01L 23/528; H01L 21/8238; H01L 27/092; H01L 29/06; H01L 29/08; H01L 29/66

(52) U.S. Cl. CPC H01L 23/5286; H10D 62/115; H10D 62/118; H10D 62/151; H10D 64/017; H10D 84/0167; H10D 84/0186; H10D 84/038; H10D 84/85

(57) ABSTRACT

A semiconductor structure includes a device layer, which in turn includes a plurality of field effect transistors, each of which has a first source-drain region, a second source-drain region, at least one channel region coupling the first and second source-drain regions; and a gate surrounding the at least one channel region. The semiconductor structure further includes a front side wiring layer with wiring coupled to the plurality of field effect transistors at a front side of the device layer; a back side power rail at a back side of the device layer; and a back side gate via interconnecting the back side power rail to the gate of at least one of the plurality of field effect transistors.

### BACKGROUND

The present invention relates generally to the electrical, electronic and computer arts and, more particularly, to integrated circuits including backside power distribution networks (BSPDNS).

BSPDNs are very attractive schemes for future integrated circuit scaling. Prior art techniques supply power from a backside power rail only to a transistor source-drain region. However, the buried power rail pitch and size can be small at small cell height, and this can cause resistance concerns. One known technique does seek to provide a gate tie down to a BSPDN, but it is formed from the front side so that the gate tie down contacts can only be formed on the sides of the channels.

### BRIEF SUMMARY

Principles of the invention provide techniques for a backside gate tie-down in backside power distribution network (BSPDN) architecture. In one aspect, an exemplary semiconductor structure includes a device layer including a plurality of field effect transistors, each having a first source-drain region, a second source-drain region, at least one channel region coupling the first and second source-drain regions; and a gate surrounding the at least one channel region. Also included are a front side wiring layer with wiring coupled to the plurality of field effect transistors at a front side of the device layer; a back side power rail at a back side of the device layer; and a back side gate via interconnecting the back side power rail to the gate of at least one of the plurality of field effect transistors.

In another aspect, an exemplary method of forming a semiconductor structure includes providing an initial structure including a substrate; a device layer, formed on the substrate, and including a plurality of field effect transistors, each having a first source-drain region, a second source-drain region, at least one channel region coupling the first and second source-drain regions; and a gate surrounding the at least one channel region; a front side wiring layer with wiring coupled to the plurality of field effect transistors at a front side of the device layer; and a carrier wafer outward of the front side wiring layer. Further steps include removing the substrate to expose a back side of the device layer; depositing backside inter-layer dielectric on the back side of the device layer; forming a gate via through the backside inter-layer dielectric to connect to the gate of at least one of the plurality of field effect transistors; and forming a backside power rail on the backside inter-layer dielectric in contact with the gate via.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor and/or on remote semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a top view of a starting structure used to fabricate one or more embodiments, wherein frontside processes have been completed and the resultant structure bonded to a carrier wafer;

FIG. 2A is a view along line X1 in FIG. 1;

FIG. 2B is a view along line Y1 in FIG. 1;

FIG. 3A is a view along line X1 in FIG. 1 and FIG. 3B is a view along line Y1 in FIG. 1, after removing the original silicon substrate;

FIG. 4A is a view along line X1 in FIG. 1 and FIG. 4B is a view along line Y1 in FIG. 1, after depositing backside inter-layer dielectric (ILD) over the structure seen in FIGS. 3A and 3B;

FIG. 5 is a top view, FIG. 6A is a view along line X1 in FIG. 5, and FIG. 6B is a view along line Y1 in FIG. 1, depicting the structure of FIGS. 4A and 4B after forming a backside gate via;

FIG. 7A is a view along line X1 in FIG. 5 and FIG. 7B is a view along line Y1 in FIG. 5, after forming a backside power rail;

FIG. 8 is a top view, FIG. 9A is a view along line X1 in FIG. 8, and FIG. 9B is a view along line Y1 in FIG. 8, depicting an alternative to the structure of FIGS. 7A and 7B with a wider backside gate via to accommodate misalignment.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein, it will be appreciated that in one aspect, an exemplary semiconductor structure includes a device layer including a plurality of field effect transistors, each having a first source-drain region, a second source-drain region, at least one channel region coupling the first and second source-drain regions; and a gate surrounding the at least one channel region. The structure further includes a front side wiring layer with wiring coupled to the plurality of field effect transistors at a front side of the device layer; a back side power rail at a back side of the device layer; and a back side gate via interconnecting the back side power rail to the gate of at least one of the plurality of field effect transistors. Technical benefits include avoiding the use of precious frontside wiring resources, reducing or eliminating the risk of channel damage in fabrication, providing flexibility in contact location, and providing enhanced density.

In some instances, the at least one of the plurality of field effect transistors that has its gate interconnected with the back side power rail using the back side gate via is a p-type field effect transistor, and the structure further includes a voltage supply terminal; the back side power rail is coupled to the voltage supply terminal. Technical benefits include enabling the above benefits with p-type or CMOS circuitry.

In some instances, the at least one of the plurality of field effect transistors that has its gate interconnected with the back side power rail using the back side gate via is an n-type field effect transistor, and the structure further includes a ground terminal; the back side power rail is coupled to the ground terminal. Technical benefits include enabling the above benefits with n-type or CMOS circuitry.

One or more embodiments further include bottom dielectric isolation (BDI) beneath the channel regions, where the gates include gate footings extending downward on either side of the channel regions, and where the back side gate via interconnects the back side power rail to the gate of at least one of the plurality of field effect transistors using one of the gate footings of the gate. Technical benefits include facilitating formation of the gate-via interface.

In some such embodiments, the gate footings extend downward lower than a lowest extension of the first and second source-drain regions. Technical benefits include facilitating formation of the gate-via interface.

In some such embodiments, the back side gate vias do not overlap the channel regions. Technical benefits include compactness.

On the other hand, some such embodiments further include a bottom dielectric isolation region, where the back side gate vias partially overlap the channel regions but are separated therefrom by the bottom dielectric isolation region. Technical benefits include toleration of misalignment.

In one or more embodiments, the back side gate via tapers from a wider dimension adjacent the back side power rail to a narrower dimension adjacent the gate of at least one of the plurality of field effect transistors. This is a consequence of backside fabrication which provides benefits as set forth herein.

In some such embodiments, the back side power rail tapers from a wider dimension towards a back side of the semiconductor structure to a narrower dimension adjacent the back side gate via. This is a consequence of backside fabrication which provides benefits as set forth herein.

In some such embodiments, the gates of the plurality of field effect transistors comprise high-K metal gate structures including high-K dielectric and gate metal. Technical benefits include manufacturability using the known HKMG process.

In some such embodiments, the high-K dielectric is selected from the group consisting of hafnium silicon oxide, zirconium silicon oxide, hafnium oxide, or zirconium oxide. Technical benefits include manufacturability using known materials.

In some such embodiments, the gate metal is a work-function-tunable material. Technical benefits include work function tunability.

In some such embodiments, the work-function-tunable material is selected from the group consisting of titanium nitride, titanium aluminum nitride, titanium silicon nitride, tantalum nitride, tantalum aluminum nitride, or tantalum silicon nitride. Technical benefits include manufacturability using known materials.

In some such embodiments, the back side gate via includes material selected from the group consisting of tungsten and ruthenium. Technical benefits include manufacturability using known materials.

In another aspect, an exemplary method of forming a semiconductor structure includes providing an initial structure, comprising a substrate; a device layer, formed on the substrate, and including a plurality of field effect transistors, each having a first source-drain region, a second source-drain region, at least one channel region coupling the first and second source-drain regions; and a gate surrounding the at least one channel region; a front side wiring layer with wiring coupled to the plurality of field effect transistors at a front side of the device layer; and a carrier wafer outward of the front side wiring layer. Further steps include removing the substrate to expose a back side of the device layer; depositing backside inter-layer dielectric on the back side of the device layer; forming a gate via through the backside inter-layer dielectric to connect to the gate of at least one of the plurality of field effect transistors; and forming a backside power rail on the backside inter-layer dielectric in contact with the gate via. Technical benefits include avoiding the use of precious frontside wiring resources, reducing or eliminating the risk of channel damage in fabrication, providing flexibility in contact location, and providing enhanced density.

In some cases, in the step of providing the initial structure, the initial structure further comprises bottom dielectric isolation (BDI) beneath the channel regions, and the gates include gate footings extending downward on either side of the channel regions; and forming the gate via through the backside inter-layer dielectric to connect to the gate includes forming the gate via to interconnect with one of the gate footings of the gate. Technical benefits include facilitating formation of the gate-via interface.

In some cases, the providing step includes forming the gates using a high-K metal replacement gate process. Technical benefits include manufacturability using the known HKMG process.

In some cases, the forming of the gates using the high-K metal replacement gate process includes forming the gates with high-K dielectric selected from the group consisting of hafnium silicon oxide, zirconium silicon oxide, hafnium oxide, or zirconium oxide and gate metal comprising a work-function-tunable material selected from the group consisting of titanium nitride, titanium aluminum nitride, titanium silicon nitride, tantalum nitride, tantalum aluminum nitride, or tantalum silicon nitride. Technical benefits include manufacturability using known materials.

In some instances, the step of forming the gate via includes forming the gate via from a material selected from the group consisting of tungsten and ruthenium. Technical benefits include manufacturability using known materials.

In some cases, the step of forming the backside power rail includes forming the backside power rail from the material selected from the group consisting of tungsten and ruthenium. Technical benefits include manufacturability using known materials.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
a gate tie down structure formed on the backside of the device in the BSPDN architecture, to overcome the prior-art problem of using precious frontside wiring resources for such a gate tie down structure;
a gate tie down structure formed on the backside of the device in the BSPDN architecture, to overcome the prior-art problem of using etching from the frontside which requires etching close to the channel which can result in channel damage, or else reduced density if the etching is spaced from the channel.

One or more embodiments provide a backside gate tie-down technique that can be used in BSPDN architecture. As noted, current backside power rails only connect to a transistor source-drain region. A gate tie-down (tying the gate of an N-type field effect transistor (NFET) to ground (GND), tying the gate of a P-type field effect transistor (PFET) to supply voltage VDD) is a convenient way of achieving device isolation. It can be considered as an electrical single diffusion break. It avoids the complicated process of a physical single diffusion break. In BSPDN architecture, a simple way of providing a gate tie-down is to connect the relevant gate to the nearest source MOL (middle of line) through frontside metal levels. However, this comes with the cost of using precious frontside wiring resources. One or more embodiments advantageously provide a gate tie down structure formed on the backside of the device in the BSPDN architecture, thereby providing an electrical single diffusion break without using frontside wiring resources.

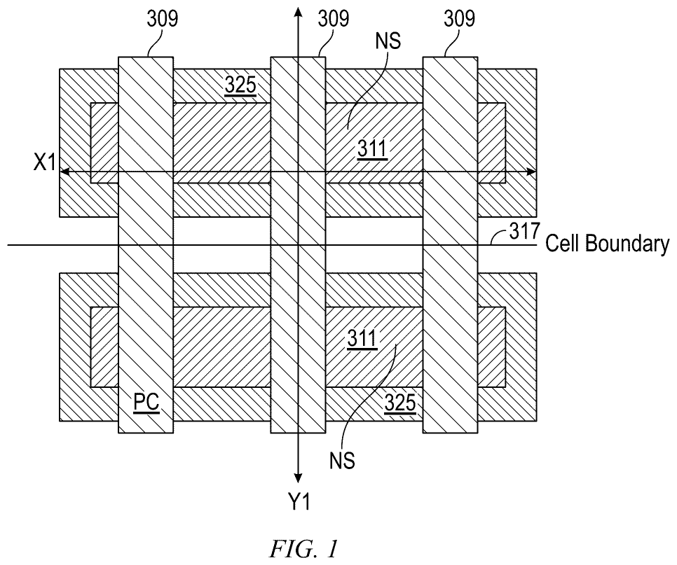

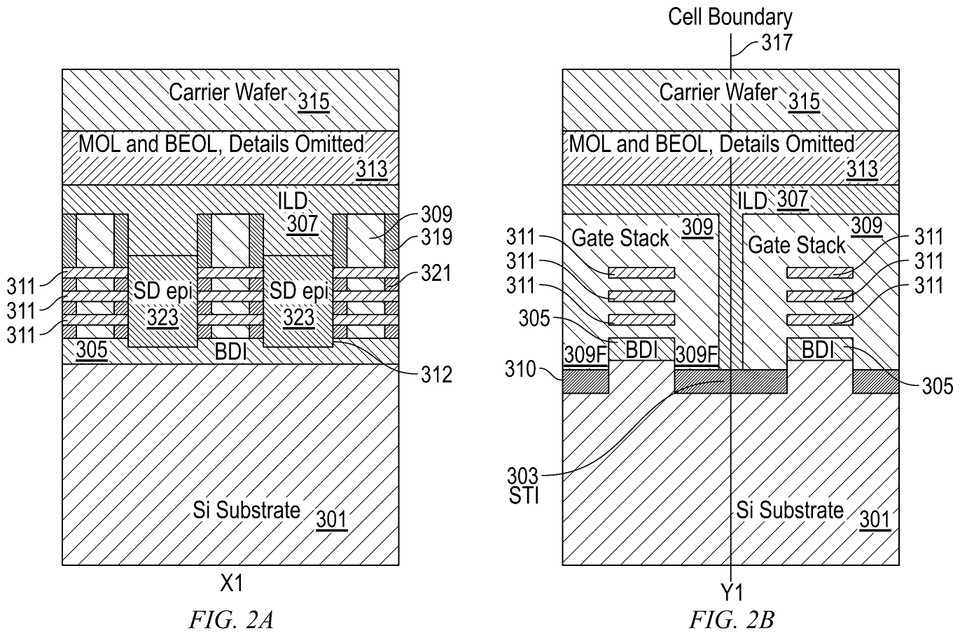

One or more embodiments achieve this desirable result using a backside gate via. Refer now to FIG. 1 (top view), FIG. 2A (view along line X1 in FIG. 1), and FIG. 2B (view along line Y1 in FIG. 1). These views represent a starting structure that will be familiar to the skilled artisan in the field of nanosheet transistor fabrication, wherein frontside processes have been completed and the resultant structure bonded to a carrier wafer. In particular, note the substrate 301, shallow trench isolation (STI) 303, bottom dielectric isolation (BDI) 305, inter-layer dielectric (ILD) 307, gate stacks 309 (gate structures), nanosheets 311, and middle of line (MOL) and back end of line (BEOL) wiring layer 313. Further note carrier wafer 315, cell boundary 317, gate spacers 319, inner spacers 321, epitaxially grown source-drain regions 323, and the outlines of the (to be formed) power rails 325. Note the gate footings 309F. Note also that the bottom 310 of the gate footing 309F extends below the bottom 312 of the source-drain epitaxy.

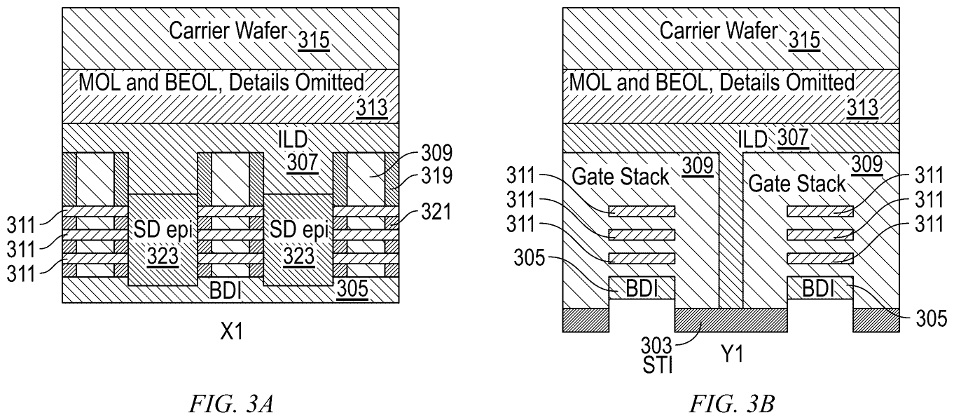

In FIG. 3A (view along line X1 in FIG. 1), and FIG. 3B (view along line Y1 in FIG. 1), remove the original silicon substrate.

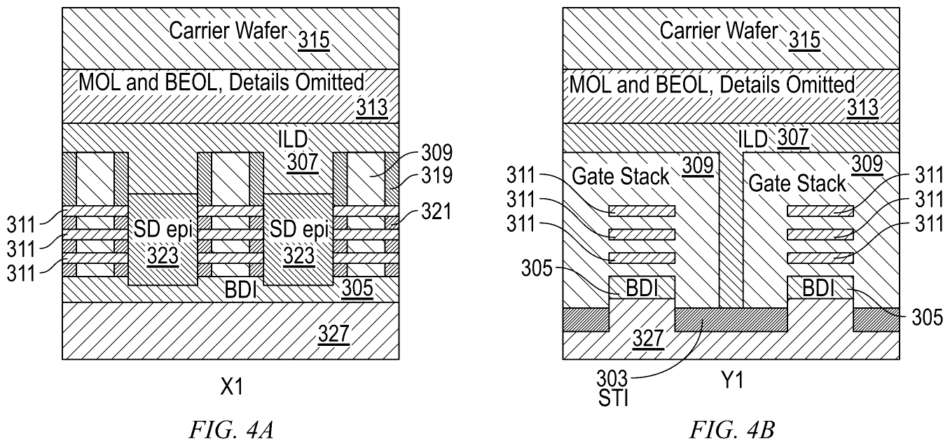

In FIG. 4A (view along line X1 in FIG. 1), and FIG. 4B (view along line Y1 in FIG. 1), deposit backside inter-layer dielectric (ILD) 327.

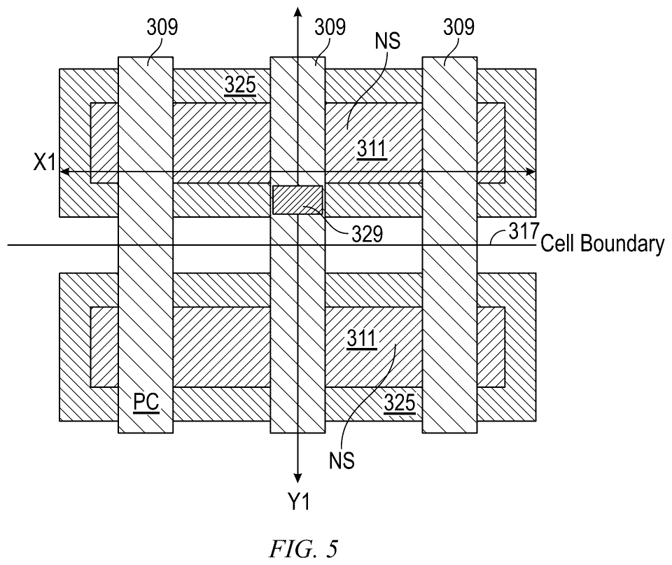

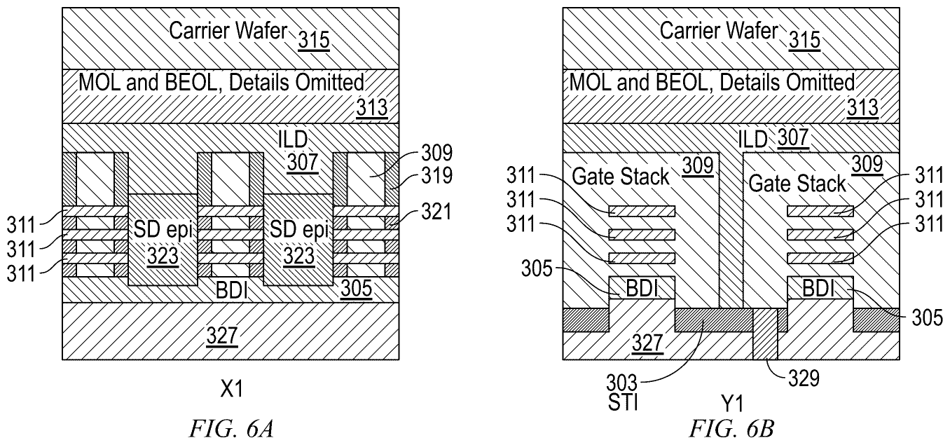

Refer now to FIG. 5 (top view), FIG. 6A (view along line X1 in FIG. 5), and FIG. 6B (view along line Y1 in FIG. 1); these depict the structure of FIGS. 4A and 4B after forming backside gate via 329.

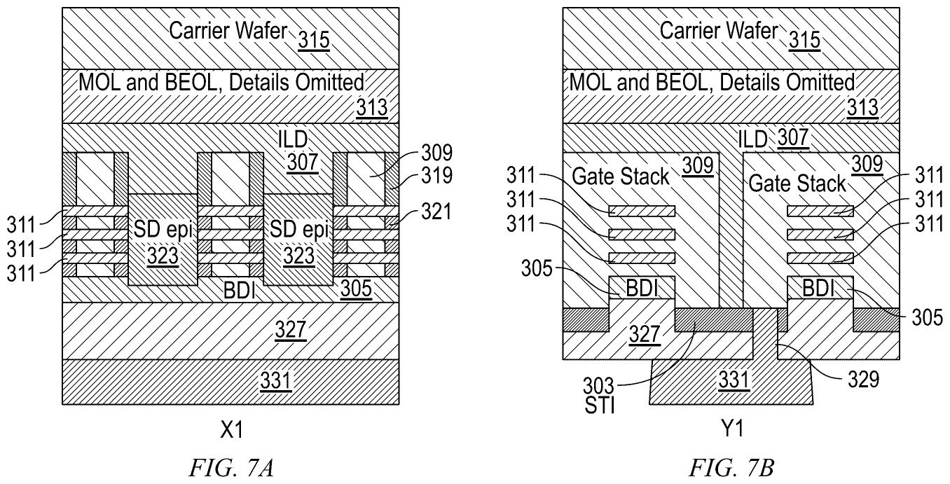

In FIG. 7A (view along line X1 in FIG. 5), and FIG. 7B (view along line Y1 in FIG. 5), form the backside power rail 331.

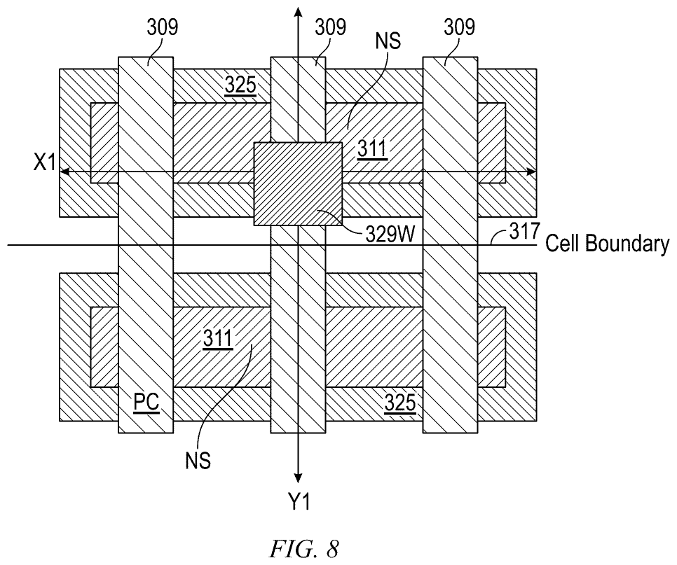

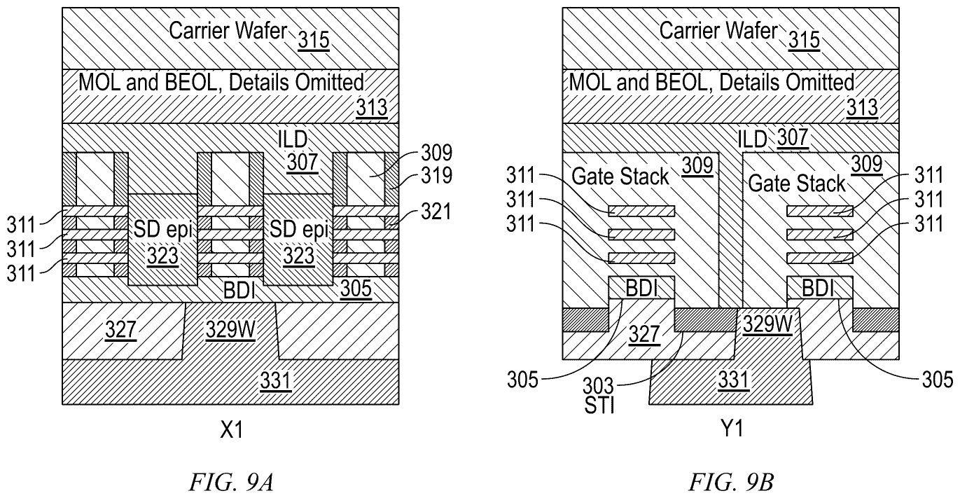

Refer now to FIG. 8 (top view), FIG. 9A (view along line X1 in FIG. 8), and FIG. 9B (view along line Y1 in FIG. 8); these depict an alternative to the structure of FIGS. 7A and 7B backside with a wider backside gate via 329W to accommodate misalignment. The wider backside gate via 329W would be formed before the backside power rail 331 in a manner analogous to FIGS. 6A and 6B (but would be visible along both X1 and Y1 as seen in FIG. 8).

It will thus be appreciated that one or more embodiments advantageously provide a backside power rail that connects to the gate. In one or more embodiments, gate footings are provided on both sides of the BDI (bottom dielectric isolation). In one or more embodiments, the bottom of the gate footings sits below the bottom of the source-drain regions. In one or more embodiments, a gate tie down contact via is formed from the backside of the wafer, which connects the backside power rail to the gate footing. Such a contact can, in some instances, partially overlap the channel.

It is worth noting that a gate tie down to a BSPDN, formed from the front side, is known in the prior art. In contrast, one or more embodiments form a gate contact and backside power rails from the back side whereas in the prior art both are formed both from the front side, so that the prior art gate tie down contact can only be formed on the side of the channels (e.g., by punching through gate materials to reach a buried power rail, followed by metallization, with potential for channel damage (or else if spaced from the channel, reducing density). Forming the tie-down connection from the back side, as in one or more embodiments, provides location flexibility. This location flexibility means that the gate tie-down contact can be close to the cell boundary but can also be overlapping the channel region. For example, one or more embodiments provide a gate tie down contact via which connects the back of the gate to a backside power rail; the same can be located near or at the cell boundary without risk of channel damage and can partially or fully overlap the channel width.

The gate stacks 309 (gate structures) can be HKMG structures where the high-K dielectric layer may include, as just a few non-limiting examples, hafnium silicon oxide, zirconium silicon oxide, hafnium oxide, or zirconium oxide. The HKMG gate metal may include, again, as just a few non-limiting examples, a work-function-tunable material such as titanium nitride, titanium aluminum nitride, titanium silicon nitride, tantalum nitride, tantalum aluminum nitride, or tantalum silicon nitride. Exemplary metallization materials for the elements 331, 329, 329 W include a thin metal adhesion layer, such as TiN liner, followed by bulk metal fill, such as Tungsten, Ruthenium, or the like.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed backside gate tie-down in backside power distribution network (BSPDN) architecture.

An integrated circuit in accordance with aspects of the present inventions can be employed in essentially any application and/or electronic system where one or more aspects of the disclosed backside gate tie-down in backside power distribution network (BSPDN) architecture would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a device layer including a plurality of field effect transistors, each having a first source-drain region, a second source-drain region, at least one channel region coupling the first and second source-drain regions; and a gate surrounding the at least one channel region;
front side wiring layer with wiring coupled to the plurality of field effect transistors at a front side of the device layer;
a back side power rail at a back side of the device layer; and
a back side gate via interconnecting the back side power rail to the gate of at least one of the plurality of field effect transistors.

2. The semiconductor structure of claim 1, wherein the at least one of the plurality of field effect transistors that has its gate interconnected with the back side power rail using the back side gate via is a p-type field effect transistor, further comprising a voltage supply terminal, wherein the back side power rail is coupled to the voltage supply terminal.

3. The semiconductor structure of claim 1, wherein the at least one of the plurality of field effect transistors that has its gate interconnected with the back side power rail using the back side gate via is an n-type field effect transistor, further comprising a ground terminal, wherein the back side power rail is coupled to the ground terminal.

4. The semiconductor structure of claim 1, further comprising bottom dielectric isolation (BDI) beneath the channel regions, wherein the gates include gate footings extending downward on either side of the channel regions, and wherein the back side gate via interconnects the back side power rail to the gate of at least one of the plurality of field effect transistors using one of the gate footings of the gate.

5. The semiconductor structure of claim 4, wherein the gate footings extend downward lower than a lowest extension of the first and second source-drain regions.

6. The semiconductor structure of claim 5, wherein the back side gate vias do not overlap the channel regions.

7. The semiconductor structure of claim 5, further comprising a bottom dielectric isolation region, wherein the back side gate vias partially overlap the channel regions but are separated therefrom by the bottom dielectric isolation region.

8. The semiconductor structure of claim 1, wherein the back side gate via tapers from a wider dimension adjacent the back side power rail to a narrower dimension adjacent the gate of at least one of the plurality of field effect transistors.

9. The semiconductor structure of claim 8, wherein the back side power rail tapers from a wider dimension towards a back side of the semiconductor structure to a narrower dimension adjacent the back side gate via.

10. The semiconductor structure of claim 8, wherein the gates of the plurality of field effect transistors comprise high-K metal gate structures including high-K dielectric and gate metal.

11. The semiconductor structure of claim 10, wherein the high-K dielectric is selected from the group consisting of hafnium silicon oxide, zirconium silicon oxide, hafnium oxide, or zirconium oxide.

12. The semiconductor structure of claim 11, wherein the gate metal is a work-function-tunable material.

13. The semiconductor structure of claim 12, wherein the work-function-tunable material is selected from the group consisting of titanium nitride, titanium aluminum nitride, titanium silicon nitride, tantalum nitride, tantalum aluminum nitride, or tantalum silicon nitride.

14. The semiconductor structure of claim 13, wherein the back side gate via includes material selected from the group consisting of tungsten and ruthenium.

15. A method of forming a semiconductor structure, comprising:
providing an initial structure comprising:
a substrate;
a device layer, formed on the substrate, and including a plurality of field effect transistors, each having a first source-drain region, a second source-drain region, at least one channel region coupling the first and second source-drain regions; and a gate surrounding the at least one channel region;
a front side wiring layer with wiring coupled to the plurality of field effect transistors at a front side of the device layer; and
a carrier wafer outward of the front side wiring layer;
removing the substrate to expose a back side of the device layer;
depositing backside inter-layer dielectric on the back side of the device layer;
forming a gate via through the backside inter-layer dielectric to connect to the gate of at least one of the plurality of field effect transistors;
forming a backside power rail on the backside inter-layer dielectric in contact with the gate via.

16. The method of claim 15, wherein:
in the step of providing the initial structure, the initial structure further comprises bottom dielectric isolation (BDI) beneath the channel regions, and the gates include gate footings extending downward on either side of the channel regions; and
forming the gate via through the backside inter-layer dielectric to connect to the gate includes forming the gate via to interconnect with one of the gate footings of the gate.

17. The method of claim 15, wherein the providing step includes forming the gates using a high-K metal replacement gate process.

18. The method of claim 17, wherein the forming of the gates using the high-K metal replacement gate process includes forming the gates with high-K dielectric selected from the group consisting of hafnium silicon oxide, zirconium silicon oxide, hafnium oxide, or zirconium oxide and gate metal comprising a work-function-tunable material selected from the group consisting of titanium nitride, titanium aluminum nitride, titanium silicon nitride, tantalum nitride, tantalum aluminum nitride, or tantalum silicon nitride.

19. The method of claim 18, wherein the step of forming the gate via includes forming the gate via from a material selected from the group consisting of tungsten and ruthenium.

20. The method of claim 19, wherein the step of forming the backside power rail includes forming the backside power rail from the material selected from the group consisting of tungsten and ruthenium.
